(19) United States
(12) Patent Application Publication
(10) Pub. No.: US 2024/0038450 A1
(43) Pub. Date: Feb. 1, 2024

(54) CAPACITOR, ELECTRIC CIRCUIT, CIRCUIT BOARD, ELECTRONIC APPARATUS, AND POWER STORAGE DEVICE

(71) Applicant: Panasonic Intellectual Property Management Co., Ltd., Osaka (JP)

(72) Inventors: Hiroki TAKEUCHI, Osaka (JP); Michio SUZUKA, Kyoto (JP)

(21) Appl. No.: 18/484,973

(22) Filed: Oct. 11, 2023

Related U.S. Application Data
(63) Continuation of application No. PCT/JP2022/007728, filed on Feb. 24, 2022.

(30) Foreign Application Priority Data
Apr. 15, 2021 (JP) 2021-069135

(51) Int. Cl. H01G 4/33; H01G 4/10

(52) U.S. Cl. CPC H01G 4/33; H01G 4/10

(57) ABSTRACT

A capacitor includes a first electrode layer, a second electrode layer, and an antiferroelectric layer. The antiferroelectric layer is disposed between the first electrode layer and the second electrode layer in a thickness direction of the first electrode layer. The antiferroelectric layer has a thickness differing from one point to another.

This application is a continuation of PCT/JP2022/007728 filed on Feb. 24, 2022, which claims foreign priority of Japanese Patent Application No. 2021-069135 filed on Apr. 15, 2021, the entire contents of both of which are incorporated herein by reference.

### BACKGROUND OF THE INVENTION

### 1. Field of the Invention

The present invention relates to a capacitor, an electrical circuit, a circuit board, an electronic device, and an electricity storage device.

### 2. Description of Related Art

Capacitors including antiferroelectrics as dielectric layers have been known.

For example, WO 2019/208340 A1 discloses a capacitor including an antiferroelectric formed of a metal oxide including HfO₂ and indicates that the metal oxide including HfO₂ can have antiferroelectricity. WO 2019/208340 A1 describes an example where part of Hf in HfO₂ included in the metal oxide forming the dielectric layer of the capacitor is substituted by an element such as Bi. In this example, by application of an external electric field from 0 MV/cm to 2 MV/cm, the dielectric constant of the dielectric layer varies between 20 and 90 depending on the electric field strength (refer to FIGS. 5 and 6). Moreover, the dielectric constant of the dielectric layer can reach the maximum in an electric field strength range of 0.5 MV/cm to 1.5 MV/cm.

JP 2013-518400 A describes a ceramic multilayer capacitor including a first capacitor unit formed of a first material and a second capacitor unit formed of a second material different from the first material. According to JP 2013-518400 A, the first material has ferroelectric properties and the second material has antiferroelectric properties.

### SUMMARY OF THE INVENTION

The techniques described in WO 2019/208340 A1 and JP 2013-518400 A need to be reexamined for ease of designing products including the capacitors. Therefore, the present disclosure provides a capacitor including an antiferroelectric and being advantageous in terms of ease of product design.

A capacitor of the present disclosure includes:
a first electrode layer;
a second electrode layer; and
an antiferroelectric layer disposed between the first electrode layer and the second electrode layer in a thickness direction of the first electrode layer, wherein
an inner portion of the first electrode layer covers the antiferroelectric layer, the inner portion surrounded by an outermost portion of the first electrode layer when the first electrode layer is viewed in plan,
an inner portion of the second electrode layer covers the antiferroelectric layer, the inner portion surrounded by an outermost portion of the second electrode layer when the second electrode layer is viewed in plan, and
the antiferroelectric layer has a thickness differing from one point to another.

A capacitor including an antiferroelectric and being advantageous in terms of ease of product design can be provided according to the present disclosure.

### BRIEF DESCRIPTION OF THE DRAWINGS

FIG. 1A is a plan view of a capacitor according to an embodiment of the present disclosure.

FIG. 1B is a cross-sectional view of the capacitor along an IB-IB line shown in FIG. 1.

FIG. 2A schematically shows an example of an electrical circuit of the present disclosure.

FIG. 2B schematically shows an example of a circuit board of the present disclosure.

FIG. 2C schematically shows an example of an electronic device of the present disclosure.

FIG. 2D schematically shows an example of an electricity storage device of the present disclosure.

FIG. 3 is a cross-sectional view of a capacitor according to another embodiment of the present disclosure.

FIG. 4 is a cross-sectional view of a capacitor according to yet another embodiment of the present disclosure.

FIG. 5A is a plan view of a capacitor according to yet another embodiment of the present disclosure.

FIG. 5B is a cross-sectional view of the capacitor along a VB-VB line shown in FIG. 5.

FIG. 6A is a plan view of a capacitor according to yet another embodiment of the present disclosure.

FIG. 6B is a cross-sectional view of the capacitor along a VIB-VIB line shown in FIG. 6A.

FIG. 7A is a plan view of a capacitor according to yet another embodiment of the present disclosure.

FIG. 7B is a cross-sectional view of the capacitor along a VIIB-VIIB line shown in FIG. 7A.

FIG. 8 is a graph showing a relation between a polarization moment of each of capacitors according to Example and Comparative Example and a magnitude of voltage between electrodes.

FIG. 9 is a graph showing a relation between a slope ΔP of a line in the graph shown in FIG. 8 and a magnitude of voltage.

### DETAILED DESCRIPTION

(Findings on which the Present Disclosure is Based)

An antiferroelectric is a material in which spontaneous polarizations caused in opposite directions by two sublattices in a crystal cancel out each other and spontaneous polarization in the crystal as a whole is zero. The dielectric constant of an antiferroelectric varies depending on the strength of an applied electric field, as described in WO 2019/208340 A1. A capacitor described in WO 2019/208340 A1 is a parallel plate capacitor, which indicates that the thickness of a dielectric layer therein is constant in an in-plane direction. In the case of a parallel plate capacitor including an antiferroelectric, an amount of change of an amount of electric charge accumulated in the capacitor with respect to an amount of change of voltage in a particular voltage range may be greatly different from that in another voltage range. This is because the dielectric constant of an antiferroelectric varies depending on the strength of an electric field applied to the antiferroelectric. This characteristic of antiferroelectrics is advantageous in terms of increasing the capacities of capacitors. However, the present inventors have newly found that some measure against this characteristic of antiferroelectrics needs to be taken in some cases from the viewpoint of ease of designing products including capacitors.

For example, in the case where a capacitor including an antiferroelectric is mounted in electrical circuits without taking any measure, the amount of electric charge accumulated in the capacitor can vary greatly depending on drive voltages of the electrical circuits. This may require selecting an appropriate composition and an appropriate thickness of the antiferroelectric for each drive voltage. Moreover, such a characteristic of capacitors including antiferroelectrics also affects selection of other devices in electrical circuits, and tends to make design of electrical circuits complicated and troublesome.

In view of these circumstances, the present inventors made intensive studies on capacitors including antiferroelectrics to take a measure against the above characteristics of antiferroelectrics from the viewpoint of ease of product design. As a result, the present inventors have newly found that a capacitor advantageous from the viewpoint of ease of product design can be achieved by a particular structure of an antiferroelectric layer of the capacitor, and have devised the capacitor of the present disclosure.

(Summary of One Aspect According to the Present Disclosure)

A capacitor according to a first aspect of the present disclosure includes:
a first electrode layer;
a second electrode layer; and
an antiferroelectric layer disposed between the first electrode layer and the second electrode layer in a thickness direction of the first electrode layer, wherein
an inner portion of the first electrode layer covers the antiferroelectric layer, the inner portion surrounded by an outermost portion of the first electrode layer when the first electrode layer is viewed in plan,
an inner portion of the second electrode layer covers the antiferroelectric layer, the inner portion surrounded by an outermost portion of the second electrode layer when the second electrode layer is viewed in plan, and
the antiferroelectric layer has a thickness differing from one point to another.

According to the first aspect, since the antiferroelectric layer has a thickness differing from one point to another, a strength of an electric field applied to the antiferroelectric layer differs from one point to another upon application of a voltage between the first electrode layer and the second electrode layer. Because of this, regardless of the characteristic of antiferroelectrics, namely, the dielectric constant varying depending on the strength of an applied electric field, an average rate of change which is a ratio of the amount of change of the amount of electric charge accumulated in the capacitor to a certain amount of change of voltage is unlikely to vary greatly in a wide voltage range. As a result, the capacitor according to the first aspect is advantageous from the viewpoint of ease of product design. Moreover, since the first electrode layer and the second electrode layer cover the antiferroelectric layer as described above, the capacitor is likely to have a large capacity. Additionally, the thickness of the antiferroelectric layer can be easily adjusted in a wide range.

According to a second aspect of the present disclosure, for example, in the capacitor according to the first aspect, the antiferroelectric layer may have a thickness of 10 nanometers (nm) or more and 1 micrometer (μm) or less. According to the second aspect, insulation failure is prevented and the capacity of the capacitor is less likely to be reduced.

According to a third aspect of the present disclosure, for example, in the capacitor according to the first or second aspect, a ratio of a maximum of the thickness of the antiferroelectric layer to a minimum of the thickness of the antiferroelectric layer may be more than 1 and less than 10. According to the third aspect, the above average rate of change is unlikely to vary greatly in a wide voltage range more reliably. Additionally, the capacity of the capacitor is less likely to be reduced.

According to a fourth aspect of the present disclosure, for example, in the capacitor according to any one of the first to third aspects, a maximum of the thickness of the antiferroelectric layer may be 500 nm or less. According to the fourth aspect, the capacitor is likely to have a large capacity. Additionally, the capacitor is likely to have a reduced thickness.

According to a fifth aspect of the present disclosure, for example, in the capacitor according to any one of the first to fourth aspects, the thickness of the antiferroelectric layer may be smaller than a thickness of the first electrode layer. According to the fifth aspect, the capacitor is likely to have a large capacity. Moreover, the capacitor is likely to have a reduced thickness.

According to a sixth aspect of the present disclosure, for example, in the capacitor according to any one of the first to fifth aspects, the thickness of the antiferroelectric layer may be smaller than a thickness of the second electrode layer. According to the sixth aspect, the capacitor is likely to have a large capacity. Moreover, the capacitor is likely to have a reduced thickness.

According to a seventh aspect of the present disclosure, for example, in the capacitor according to any one of the first to sixth aspects, the thickness of the antiferroelectric layer may vary continuously or stepwise in a particular in-plane direction. According to the seventh aspect, since the antiferroelectric layer can have various thickness values, the above average rate of change is unlikely to vary greatly in a wide voltage range more reliably.

According to an eighth aspect of the present disclosure, for example, in the capacitor according to the seventh aspect, the thickness of the antiferroelectric layer may vary continuously or stepwise from one end to the other end in a particular in-plane direction. According to the eighth aspect, since the antiferroelectric layer can have various thickness values from one end to the other end in the particular in-plane direction, the above average rate of change is unlikely to vary greatly in a wide voltage range more reliably.

According to a ninth aspect of the present disclosure, for example, in the capacitor according to any one of the first to eighth aspects, the antiferroelectric layer may include a first region and a second region, the first region having a minimum thickness and having a given area in plan view, the second region having a maximum thickness and having a given area in plan view. Additionally, a ratio of the area of the second region in plan view to the area of the first region in plan view may be more than 1 and less than 10. According to the ninth aspect, when a voltage is applied between the first electrode layer and the second electrode layer, a spatial distribution of the strength of an electric field applied to the antiferroelectric layer is likely to be a desired one. Consequently, the above average rate of change is unlikely to vary greatly in a wide voltage range more reliably.

According to a tenth aspect of the present disclosure, for example, in the capacitor according to any one of the first to ninth aspects, the antiferroelectric layer may include a connecting portion between a pair of regions having different thicknesses, the connecting portion defining a step corresponding to a difference between the thicknesses of the pair of regions. According to the tenth aspect, the connecting portion is likely to be so small in the antiferroelectric layer that the pair of regions are easily extended. Additionally, production of the antiferroelectric layer is likely to be easy.

According to an eleventh aspect of the present disclosure, for example, in the capacitor according to any one of the first to tenth aspects, the antiferroelectric layer may include a connecting portion between a pair of regions having different thicknesses, the connecting portion having a thickness varying continuously or stepwise from one of the pair of regions toward the other. According to the eleventh aspect, the second electrode layer on the pair of regions is unlikely to be divided by a step. Moreover, adhesion failure between the antiferroelectric layer and the second electrode layer is likely to be prevented. Consequently, the capacitor is likely to have a high reliability.

According to a twelfth aspect of the present disclosure, for example, in the capacitor according to any one of the first to eleventh aspects, the antiferroelectric layer may include a plurality of particular regions each having a particular thickness and having a given area in plan view. Additionally, the particular regions are disposed apart from each other when the antiferroelectric layer is viewed in plan from the second electrode layer. According to the twelfth aspect, a load is likely to be applied to dispersed positions on the antiferroelectric layer, and the capacitor is likely to have a high robustness.

According to a thirteenth aspect of the present disclosure, for example, in the capacitor according to the twelfth aspect, the particular regions may be disposed regularly when the antiferroelectric layer is viewed in plan from the second electrode layer. According to the thirteenth aspect, the capacitor is likely to have a high robustness more reliably.

According to a fourteenth aspect of the present disclosure, for example, in the capacitor according to the twelfth or thirteenth aspect, each of the particular regions may be in a shape of a belt parallel to another belt when the antiferroelectric layer is viewed in plan from the second electrode layer. According to the fourteenth aspect, the capacitor is likely to have a high robustness more reliably.

According to a fifteenth aspect of the present disclosure, for example, in the capacitor according to the twelfth or thirteenth aspect, each of the particular regions may be in a circular or rectangular shape when the antiferroelectric layer is viewed in plan from the second electrode layer. According to the fifteenth aspect, the capacitor is likely to have a high robustness more reliably.

According to a sixteenth aspect of the present disclosure, for example, the capacitor according to any one of the first to fifteenth aspects, the antiferroelectric layer may include a metal oxide including at least one of hafnium and zirconium. According to the sixteenth aspect, the capacitor is likely to have a desired capacity.

According to a seventeenth aspect of the present disclosure, for example, the capacitor according to any one of the first to sixteenth aspects, the antiferroelectric layer may further include a support, and the first electrode layer may be disposed between the support and the antiferroelectric layer in the thickness direction of the first electrode layer. According to the seventeenth aspect, the support can support a layered body including the first electrode layer, the antiferroelectric layer, and the second electrode layer, and the capacitor is likely to have a high mechanical strength.

According to an eighteenth aspect of the present disclosure, for example, in the capacitor according to any one of the seventeenth aspect, the support may have no empty space overlapping the antiferroelectric layer in plan view. According to the eighteenth aspect, the capacitor is likely to have a much higher mechanical strength.

An electrical circuit according to a nineteenth aspect of the present disclosure includes the capacitor according to any one of the first to eighteenth aspects. According to the nineteenth aspect, the electrical circuit is easily designed.

A circuit board according to a twentieth aspect of the present disclosure includes the capacitor according to any one of the first to eighteenth aspects. According to the twentieth aspect, the circuit board is easily designed.

An electronic device according to a twenty-first aspect of the present disclosure includes the capacitor according to any one of the first to eighteenth aspects. According to the twenty-first aspect, the electronic device is easily designed.

An electricity storage device according to a twenty-second aspect of the present disclosure includes the capacitor according to any one of the first to eighteenth aspects. According to the twenty-second aspect, the electricity storage device is easily designed.

### EMBODIMENTS

Embodiments of the present disclosure will be described hereinafter with reference to the drawings. The present disclosure is not limited to the following embodiments. In the description below, words (e.g., “above”, “on”, “below”, “left”, “right” and other words having similar meanings) referring to particular directions and positions are used as necessary. These words are used with the aim of facilitating understanding of the invention with reference to the drawings, and the meanings of these words do not limit the technical scope of the present disclosure.

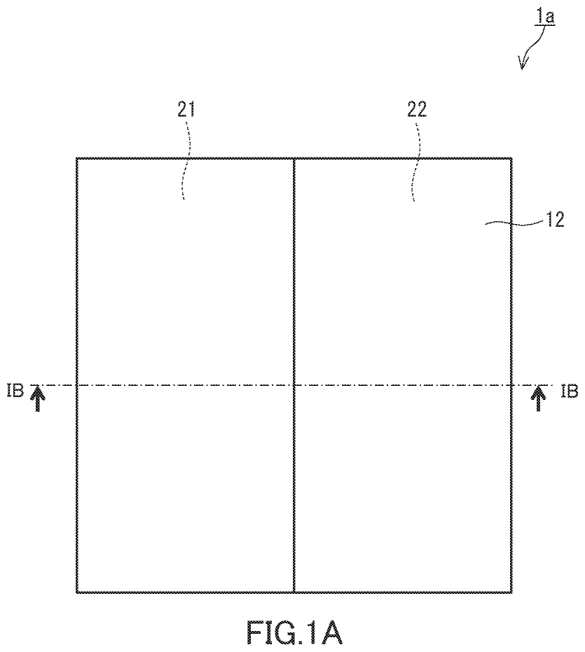

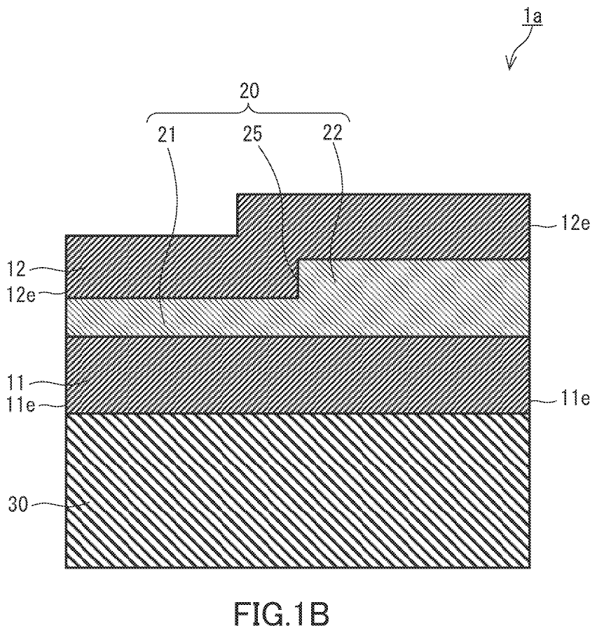

FIGS. 1A and 1B are respectively a plan view and a cross-sectional view of a capacitor 1a according to an example of an embodiment of the present disclosure. As shown in FIGS. 1A and 1B, the capacitor 1a includes a first electrode layer 11, a second electrode layer 12, and an antiferroelectric layer 20. The antiferroelectric layer 20 is disposed between the first electrode layer 11 and the second electrode layer 12 in a thickness direction of the first electrode layer 11. An inner portion of the first electrode layer covers the antiferroelectric layer, the inner portion surrounded by an outermost portion of the first electrode layer 11 when the first electrode layer 11 is viewed in plan. Additionally, an inner portion of the second electrode layer 12 covers the antiferroelectric layer 20, the inner portion surrounded by an outermost portion 12e of the second electrode layer 12 when the second electrode layer 12 is viewed in plan. The first electrode layer 11 and the second electrode layer 12 are each a layer, for example, free of openings and gaps in plan view. With such structural features, the capacitor 1a is likely to have a large capacity. Additionally, a thickness of the antiferroelectric layer 20 can be easily adjusted in a wide range. The antiferroelectric layer 20 has a thickness differing from one point to another. Under application of a voltage between the first electrode layer 11 and the second electrode layer 12, the strength of an electric field applied to the antiferroelectric layer 20 differs from one point to another. In other words, a value of the strength of the electric field applied to the antiferroelectric layer 20 can vary widely. Because of this, although the capacitor 1a includes the antiferroelectric layer 20 as a dielectric layer, an average rate of change which is a ratio of an amount of change of an amount of electric charge accumulated in the capacitor 1a to a certain amount of change of voltage is less likely to greatly vary in a wide voltage range. For this reason, the capacitor 1a is advantageous from the viewpoint of ease of product design.

The thickness of the antiferroelectric layer 20 is not limited to a particular value. The antiferroelectric layer 20 has a thickness of, for example, 10 nm or more and 1 μm or less. For example, the thickness of the antiferroelectric layer 20 is within this range across the entire antiferroelectric layer 20. When the thickness of the antiferroelectric layer 20 is 10 nm or more, the antiferroelectric layer 20 is likely to be free of pinholes and insulation failure can be prevented. The capacity of a capacitor is in inverse proportion to the thickness of a dielectric layer thereof. When the thickness of the antiferroelectric layer 20 is 1 μm or less, the capacity of the capacitor 1a is less likely to be reduced. The thickness of the antiferroelectric layer 20 can be determined, for example, by electron microscope observation of a cross-section of the capacitor 1a, the cross-section being perpendicular to a principal surface of the first electrode layer 11.

A ratio of a maximum of the thickness of the antiferroelectric layer 20 to a minimum of the thickness of the antiferroelectric layer 20 is not limited to a particular value. The ratio is, for example, more than 1 and less than 10. In this case, the above average rate of change is unlikely to vary greatly in a wide voltage range more reliably. Additionally, the capacity of the capacitor 1a is less likely to be reduced. The ratio of the maximum of the thickness of the antiferroelectric layer 20 to the minimum of the thickness of the antiferroelectric layer 20 may be 1.1 or more, 1.2 or more, 1.5 or more, or 2 or more. The ratio of the maximum of the thickness of the antiferroelectric layer 20 to the minimum of the thickness of the antiferroelectric layer 20 may be 9 or less, 8 or less, 7 or less, 6 or less, or 5 or less.

The maximum of the thickness of the antiferroelectric layer 20 may be less than 1 μm, or desirably 500 nm or less. In these cases, the capacitor 1a is likely to have a large capacity. Moreover, the capacitor 1a is likely to have a reduced thickness. The maximum of the thickness of the antiferroelectric layer 20 may be 300 nm or less, 200 nm or less, 100 nm or less, 50 nm or less, or 20 nm or less.

A relation between the thickness of the antiferroelectric layer 20 and the thickness of the first electrode layer 11 is not limited to a particular relation. The thickness of the antiferroelectric layer 20 is, for example, smaller than the thickness of the first electrode layer 11. With such a structural feature, the capacitor 1a is likely to have a large capacity. Moreover, the capacitor 1a is likely to have a reduced thickness. The thickness of the antiferroelectric layer 20 may be greater than the thickness of the first electrode layer 11.

A relation between the thickness of the antiferroelectric layer 20 and the thickness of the second electrode layer 12 is not limited to a particular relation. The thickness of the antiferroelectric layer 20 is, for example, smaller than the thickness of the second electrode layer 12. With such a structural feature, the capacitor 1a is likely to have a large capacity. Moreover, the capacitor 1a is likely to have a reduced thickness. The thickness of the antiferroelectric layer 20 may be greater than the thickness of the second electrode layer 12.

As shown in FIGS. 1A and 1B, the antiferroelectric layer 20 includes, for example, a first region 21 and a second region 22. The first region 21 and the second region 22 have different thicknesses. The first region 21, for example, has a minimum thickness in the antiferroelectric layer 20 and has a given area in plan view. For example, the thickness of the first region 21 is constant or considered constant across the entire first region 21. For example, the thickness of a region can be considered constant in the case where thickness data is obtained by measuring thicknesses at 10 or more points randomly selected in the region and a difference between the largest value and the average value and a difference between the average value and the smallest value are 10% or less of the average value. The second region 22, for example, has a maximum thickness in the antiferroelectric layer 20 and has a given area in plan view. For example, the thickness of the second region 22 is constant or considered constant across the second region 22. A ratio of the area of the second region 22 in plan view to the area of the first region 21 in plan view is not limited to a particular value. The ratio is, for example, more than 1 and less than 10. In this case, when a voltage is applied between the first electrode layer 11 and the second electrode layer 12, a spatial distribution of the strength of an electric field applied to the antiferroelectric layer 20 is likely to be a desired one. As a result, the above average rate of change is unlikely to vary greatly in a wide voltage range more reliably. The ratio of the area of the second region 22 in plan view to the area of the first region 21 in plan view may be 1.5 or more, 2 or more, or 3 or more. The ratio of the area of the second region 22 in plan view to the area of the first region 21 in plan view may be 9 or less, 8 or less, or 7 or less.

As shown in FIG. 1B, the antiferroelectric layer 20 includes, for example, a connecting portion 25. The connecting portion 25 is positioned between the first region 21 and the second region 22. The connecting portion 25 defines, for example, a step corresponding to a difference between the thicknesses of the first region 21 and the second region 22. With such a structural feature, in the antiferroelectric layer 20, the connecting portion 25 is likely to be small and the area of the first region 21 or the second region 22 is easily increased.

An antiferroelectric included in the antiferroelectric layer 20 is not limited to a particular substance as long as the antiferroelectric has antiferroelectricity. The antiferroelectric layer 20 as a whole typically has a uniform composition and phase. The antiferroelectric layer 20 includes, for example, a metal oxide including at least one of hafnium and zirconium. Because of this, the capacitor 1a is likely to have a desired capacity. Examples of the metal oxide including at least one of hafnium and zirconium include oxides, such as HfO₂, ZrO₂, and Hf₁₋ₓZrₓO₂, having a fluorite structure. The symbol x satisfies a requirement 0<x<1. The metal oxide may be an oxide in which part of Hf in HfO₂ or Hf₁₋ₓZrₓO₂ is substituted by Si or Al. The metal oxide may be an oxide in which part of Zr in ZrO₂ or Hf₁₋ₓZrₓO₂ is substituted by Y, Ti, Sn, or Ce. The antiferroelectric included in the antiferroelectric layer 20 may be another metal oxide having a fluorite structure or an oxide having a perovskite structure. Examples of the oxide having a perovskite structure include PbZr_{y}Ti_{1-y}O₃, NaNbO₃, and AgNbO₃. The symbol y satisfies a requirement 0<y<1.

As shown in FIG. 1B, the first electrode layer 11 is, for example, in contact with the antiferroelectric layer 20. The thickness of the first electrode layer 11 is not limited to a particular value. The thickness of the first electrode layer 11 is, for example, 100 nm or more. In this case, the capacitor 1a is likely to have a low internal resistance. The thickness of the first electrode layer 11 is, for example, 500 nm or less. In this case, the entire capacitor 1a is likely to have a large capacity density.

The material of the first electrode layer 11 is not limited to a particular material. The material of the first electrode layer 11 may be a metal such as Pt, Au, Al, Ta, or Zr. The material of the first electrode layer 11 may be an electrically conductive nitride such as TiN or TaN, or an electrically conductive oxide such as indium tin oxide (ITO), antimony tin oxide (ATO), or ZnO. The material of the first electrode layer 11 is, desirably, Pt, Au, ITO, or ZnO in the case where a process of forming the antiferroelectric layer 20 on the first electrode layer 11 is performed in an oxidative atmosphere. The material of the first electrode layer 11 is, desirably, Pt, Au, Al, Ta, Zr, TiN, or TaN in the case where a process of forming the antiferroelectric layer 20 on the first electrode layer 11 is performed in a reducing atmosphere.

As shown in FIG. 1B, the second electrode layer 12 is, for example, in contact with the antiferroelectric layer 20. The second electrode layer 12 is in contact with both the first region 21 and the second region 22. The second electrode layer 12 is also in contact with the connecting portion 25.

The thickness of the second electrode layer 12 is not limited to a particular value. The thickness of the second electrode layer 12 is, for example, 100 nm or more. In this case, the capacitor 1a is likely to have a low internal resistance. The thickness of the second electrode layer 12 is, for example, 500 nm or less. In this case, the entire capacitor 1a is likely to have a large capacity density.

The material of the second electrode layer 12 is not limited to a particular material. The material of the second electrode layer 12 may be a metal such as Pt, Au, Al, Ta, or Zr. The material of the second electrode layer 12 may be an electrically conductive nitride such as TiN or TaN, or an electrically conductive oxide such as ITO, ATO, or ZnO. After the second electrode layer 12 is formed, an annealing treatment may be performed for crystallization of the material of the antiferroelectric layer 20. The material of the second electrode layer 12 is, desirably, Pt, Au, ITO, or ZnO in the case where an atmosphere around the second electrode layer 12 becomes an oxidative atmosphere due to a gas supplied around the second electrode layer 12 in the annealing treatment. The material of the second electrode layer 12 is, desirably, Pt, Au, Al, Ta, Zr, TiN, or TaN in the case where the atmosphere around the second electrode layer 12 becomes a reducing atmosphere in the annealing treatment.

As shown in FIG. 1B, the capacitor 1a further includes, for example, a support 30. The first electrode layer 11 is disposed between the support 30 and the antiferroelectric layer 20 in the thickness direction of the first electrode layer 11. The support 30 can support a layered body including the first electrode layer 11, the antiferroelectric layer 20, and the second electrode layer 12, and the capacitor 1a is likely to have a high mechanical strength. The support 30 can be used, for example, as a substrate for formation of the first electrode layer 11. In the capacitor 1a, the support 30 may be omitted.

The support 30 may be an electric conductor, a semiconductor, or an insulator. When the support 30 is an electric conductor, the support 30 and the first electrode layer 11 may be integrated. In this case, the thickness of the first electrode layer 11 may be more than 500 nm.

A thickness of the support 30 is not limited to a particular value. The thickness of the support 30 is, for example, 5 μm or more and 1 mm or less.

The support 30 has, for example, no empty space overlapping the antiferroelectric layer 20 in plan view. With such a structural feature, the capacitor 1a is likely to have a higher mechanical strength.

In the capacitor 1a, a potential difference occurs in the antiferroelectric layer 20 by application of a voltage between the first electrode layer 11 and the second electrode layer 12. Magnitudes of the potential differences occurring in the first region 21 and the second region 22 are the same. Meanwhile, an electric field strength is a potential difference per unit thickness of a dielectric layer, and a dimension thereof is V/m. Since the first region 21 and the second region 22 have different thicknesses, the electric field strengths in the first region 21 and the second region 22 are different from each other. The dielectric constant of an antiferroelectric varies according to the electric field strength. Therefore, the dielectric can have different dielectric constants in the first region 21 and the second region 22 although the first region 21 and the second region 22 are formed of the same type of antiferroelectric.

The dielectric constants of most antiferroelectrics tend to increase with increase in electric field strength and then slightly decrease with further increase in electric field strength. Because of this, a voltage applied to achieve a maximum dielectric constant in the first region 21 is different from that in the second region 22. Consequently, even if a ratio of the amount of change in dielectric constant to a certain amount of change in voltage is large in one of the first region 21 and the second region 22, the ratio of the amount of change in dielectric constant to the certain amount of change in voltage is likely to be small in the other region. This can prevent the ratio of the amount of change in dielectric constant to the certain amount of change in voltage from greatly varying across the entire antiferroelectric layer 20 in a given voltage range. Consequently, for the capacitor 1a, the average rate of change which is the ratio of the amount of change of the amount of electric charge accumulated in the capacitor to a certain amount of change in voltage is less likely to greatly vary in a wide voltage range, compared to a capacitor including an antiferroelectric layer having a uniform thickness. Therefore, the capacitor 1a is advantageous from the viewpoint of ease of designing products such as electrical circuits.

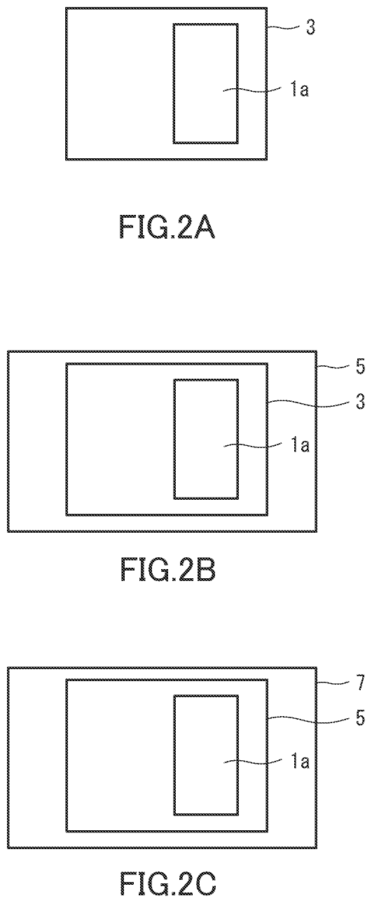

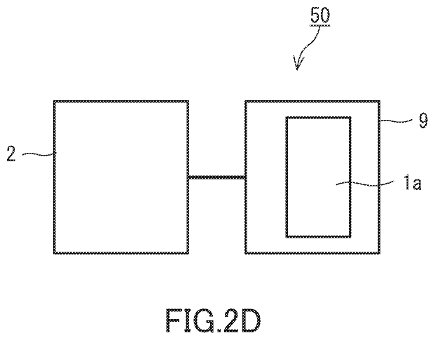

As shown in FIG. 2A, for example, an electrical circuit 3 including the capacitor 1a can be provided. The electrical circuit 3 is not limited to a particular circuit as long as the electrical circuit 3 includes the capacitor 1a. The electrical circuit 3 may be an active circuit or a passive circuit. The electrical circuit 3 may be a discharging circuit, a smoothing circuit, a decoupling circuit, or a coupling circuit. Since the electrical circuit 3 includes the capacitor 1a, the electrical circuit 3 is easily designed.

As shown in FIG. 2B, for example, a circuit board 5 including the capacitor 1a can be provided. Since the circuit board 5 includes the capacitor 1a, the circuit board 5 is easily designed. For example, the electrical circuit 3 including the capacitor 1a is placed on the circuit board 5.

As shown in FIG. 2C, for example, an electronic device 7 including the capacitor 1a can be provided. Since the electronic device 7 includes the capacitor 1a, the electronic device 7 is easily designed. For example, the electronic device 7 includes the circuit board 5 including the capacitor 1a. The electronic device is, for example, an information terminal such as a smartphone or a tablet PC.

As shown in FIG. 2D, for example, an electricity storage device 9 including the capacitor 1a can be provided. Since the electricity storage device 9 includes the capacitor 1a, the electricity storage device 9 is easily designed. For example, an electricity storage system 50 can be provided using the electricity storage device 9. The electricity storage system 50 includes the electricity storage device 9 and a power generator 2. In the electricity storage system 50, electricity generated by the power generator 2 is stored in the electricity storage device 9. The power generator 2 is, for example, an apparatus for photovoltaic power generation or wind power generation. The electricity storage device 9 is a device, for example, including a lithium-ion battery or a lead storage battery.

An example of the method for producing the capacitor 1a will be described. First, the first electrode layer 11 is formed on a principal surface of the support 30. For example, a vacuum process, plating, or coating can be applied to the formation of the first electrode layer 11. Examples of the vacuum process include DC sputtering, RF magnetron sputtering, pulsed laser deposition (PLD), atomic layer deposition (ALD), and chemical vapor deposition (CVD). A metallic foil such as an aluminum foil or a copper foil may be used as the support 30, and the support 30 and the first electrode layer 11 may be configured integrally. In one example, a thin TiN film serving as the first electrode layer 11 is formed on a principal surface of a Si substrate serving as the support 30 by RF magnetron sputtering.

Next, the antiferroelectric layer 20 is formed on the first electrode layer 11. The vacuum process mentioned as an example of the method for forming the first electrode layer 11 can be applied to the formation of the antiferroelectric layer 20. A wet process, such as dip coating, spin coating, or die coating, using chemical solution deposition (CSD) may be applied to the formation of the antiferroelectric layer 20. In one example, a thin Hf_{0.48}Zr_{0.48}Si_{0.04}O₂ film is formed as the antiferroelectric layer 20 by RF magnetron sputtering. The first region 21 is formed, for example, by placing, in the middle of deposition of the material of the antiferroelectric layer 20 by RF magnetron sputtering, a metal mask directly above a place where the first region 21 is to be formed. The metal mask can be placed at a given position on a straight line connecting a sputtering target and a deposit of the material of the antiferroelectric layer 20. The deposition of the material of the antiferroelectric layer 20 stops in the region covered by the metal mask, so that the first region 21 having a smaller thickness is formed. On the other hand, the deposition of the material of the antiferroelectric layer 20 continues in a region not covered by the metal mask to form the second region 22 having a larger thickness. The thin Hf_{0.48}Zr_{0.48}Si_{0.04}O₂ film can be formed, for example, under a condition where an amorphous structure is formed. The thin Hf_{0.48}Zr_{0.48}Si_{0.04}O₂ film having an amorphous structure has paraelectricity and does not have antiferroelectricity. Because of this, the thin Hf_{0.48}Zr_{0.48}Si_{0.04}O₂ film having an amorphous structure is subjected to rapid thermal anneal (RTA) to crystallize the thin Hf_{0.48}Zr_{0.48}Si_{0.04}O₂ film into a tetragonal phase. The resulting thin Hf_{0.48}Zr_{0.48}Si_{0.04}O₂ film has antiferroelectricity. Thus the antiferroelectric layer 20 is obtained.

Next, the second electrode layer 12 is formed on the antiferroelectric layer 20. A vacuum process, plating, or coating can be applied to the formation of the second electrode layer 12, as in the formation of the first electrode layer 11. In one example, an Au electrode serving as the second electrode layer 12 is formed by vacuum deposition.

In the capacitor 1a, the antiferroelectric layer 20 includes, for example, two regions having different thicknesses, as described above. The antiferroelectric layer 20 may include three or more regions having different thicknesses.

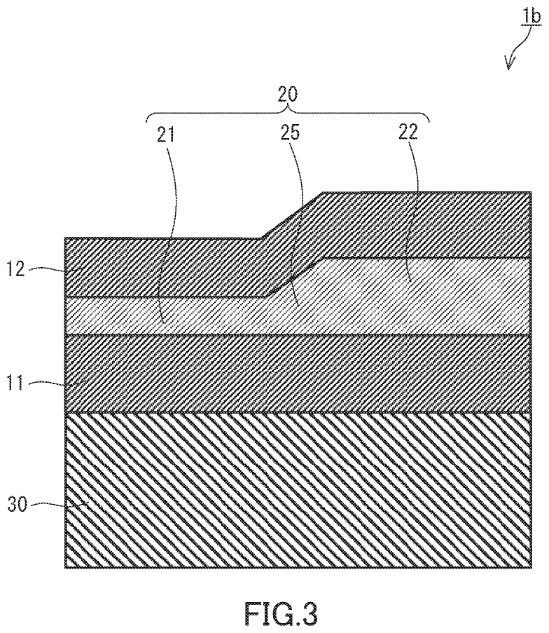

FIG. 3 is a cross-sectional view showing a capacitor 1b according to another example of the embodiment of the present disclosure. The capacitor 1b is configured in the same manner as the capacitor 1a unless otherwise described. The components of the capacitor 1b that are the same as or correspond to the components of the capacitor 1a are denoted by the same reference characters, and detailed descriptions of such components are omitted. The description given for the capacitor 1a is applicable to the capacitor 1b unless there is a technical inconsistency.

As shown in FIG. 3, in the capacitor 1b, the antiferroelectric layer 20 has a thickness varying continuously in a particular in-plane direction. Therefore, the antiferroelectric layer 20 can have various thickness values, and thus the above average rate of change is unlikely to vary greatly in a wide voltage range more reliably. The antiferroelectric layer 20 may have a thickness varying stepwise in a particular in-plane direction.

As shown in FIG. 3, the antiferroelectric layer 20 includes the connecting portion 25. The connecting portion 25 is placed between the first region 21 and the second region 22. The connecting portion 25 has a thickness varying continuously from the first region 21 toward the second region 22. The connecting portion 25 has, for example, a thickness varying monotonously between the first region 21 and the second region 22. The connecting portion 25 may have a thickness varying stepwise from the first region 21 toward the second region 22.

The connecting portion 25 has a thickness, for example, increasing continuously from the first region 21 toward the second region 22. A surface of the connecting portion 25 is, for example, inclined to a principal surface of the first electrode layer 11 at a given angle, the principal surface being in contact with the antiferroelectric layer 20. The angle is, for example, 30° or more and 60° or less.

An example of the method for forming the connecting portion 25 as described above will be described. In the case of forming the antiferroelectric layer 20 by RF magnetron sputtering, a metal mask is disposed above a region to be the first region 21 in the middle of the thin film formation. After that, a state where the material of the antiferroelectric layer 20 is not deposited on the region to be the first region 21 is maintained. Then, until deposition of the material of the antiferroelectric layer 20 in a region to be the second region 22 is completed, the metal mask is moved only a distance corresponding to the connecting portion 25 at a constant velocity toward a space above the region to be the second region 22. Alternatively, a metal mask inserted between a sputtering target and the first electrode layer 11 is disposed away from a region where the antiferroelectric layer 20 is to be formed. In this case, particles sputtered from the sputtering target can go behind the metal mask to form the connecting portion 25. With the connecting portion 25 formed in this manner, the second electrode layer 12 is unlikely to be divided on the first region 21 and the second region 22 by a step. Moreover, adhesion failure between the antiferroelectric layer 20 and the second electrode layer 12 is likely to be prevented. Consequently, the capacitor 1b is likely to have a high reliability.

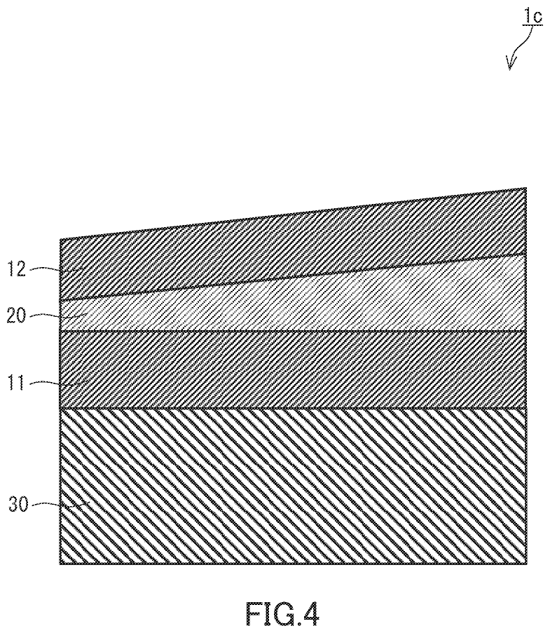

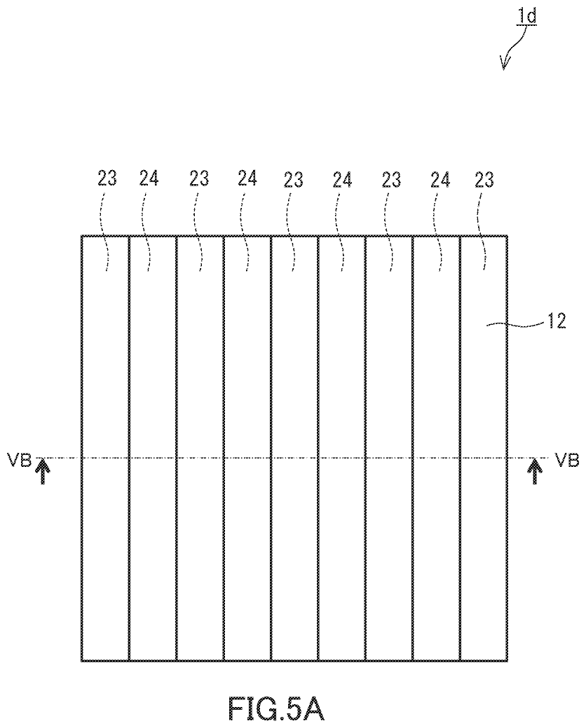

FIG. 4 is a cross-sectional view of a capacitor 1c according to yet another example of the embodiment of the present disclosure. The capacitor 1c is configured in the same manner as the capacitor 1a unless otherwise described. The components of the capacitor 1c that are the same as or correspond to the components of the capacitor 1a are denoted by the same reference characters, and detailed descriptions of such components are omitted. The description given for the capacitor 1a is applicable to the capacitor 1c unless there is a technical inconsistency.

As shown in FIG. 4, in the capacitor 1c, the antiferroelectric layer 20 has a thickness varying continuously in a particular in-plane direction.

The antiferroelectric layer 20 has, for example, a thickness varying continuously from one end to the other end in a particular in-plane direction. With such a structural feature, the antiferroelectric layer 20 can have various thickness values from one end to the other end in the particular in-plane direction of the antiferroelectric layer 20. In this case, the above average rate of change is unlikely to vary greatly in a wide voltage range more reliably. The antiferroelectric layer 20 may have a thickness varying stepwise from one end to the other end in a particular in-plane direction.

The antiferroelectric layer 20 has a thickness, for example, increasing continuously from one end to the other end in a particular in-plane direction. The antiferroelectric layer 20 has a thickness, for example, increasing continuously from one end to the other end in a particular in-plane direction. The antiferroelectric layer 20 has a thickness, for example, varying monotonously from one end to the other end in a particular in-plane direction. The antiferroelectric layer 20 has a thickness, for example, increasing monotonously from one end to the other end in a particular in-plane direction. The antiferroelectric layer 20 is formed, for example, such that a ratio of an amount of change of the thickness to an amount of change of a distance between one end to the other end in a particular in-plane direction is fixed.

An example of the method for forming the antiferroelectric layer 20 as described above will be described. In the case of forming the antiferroelectric layer 20 by RF magnetron sputtering, the material of the antiferroelectric layer 20 is deposited to only a given thickness. After that, a metal mask is moved at a constant velocity from left to right in FIG. 4 while the layer is being formed. The material of the antiferroelectric layer 20 is not deposited on a region covered with the metal mask. As a result, in FIG. 4, the thickness of the antiferroelectric layer 20 is smaller on the left side, while the thickness of the antiferroelectric layer 20 is larger on the right side where was covered by the metal mask for a shorter period of time. In this manner, the antiferroelectric layer 20 is formed such that the ratio of the amount of change of the thickness to the amount of change of the distance between one end to the other end in a particular in-plane direction is fixed. Alternatively, the antiferroelectric layer 20 can be formed by performing sputtering with the first electrode layer 11 inclined to a sputtering target instead of in parallel to a sputtering target. In this case, the thickness of the antiferroelectric layer 20 is likely to be larger in a region to which a distance from the target is shorter, while the thickness of the antiferroelectric layer 20 is likely to be smaller in another region to which the distance from the target is longer, the regions each being on the first electrode layer 11. The antiferroelectric layer 20 formed in this manner can be considered to include a number of tiny regions having different thicknesses, and can have various thickness values.

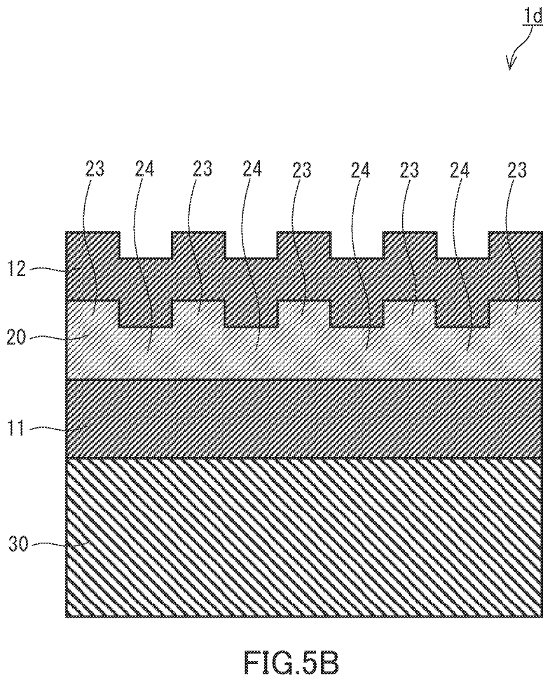

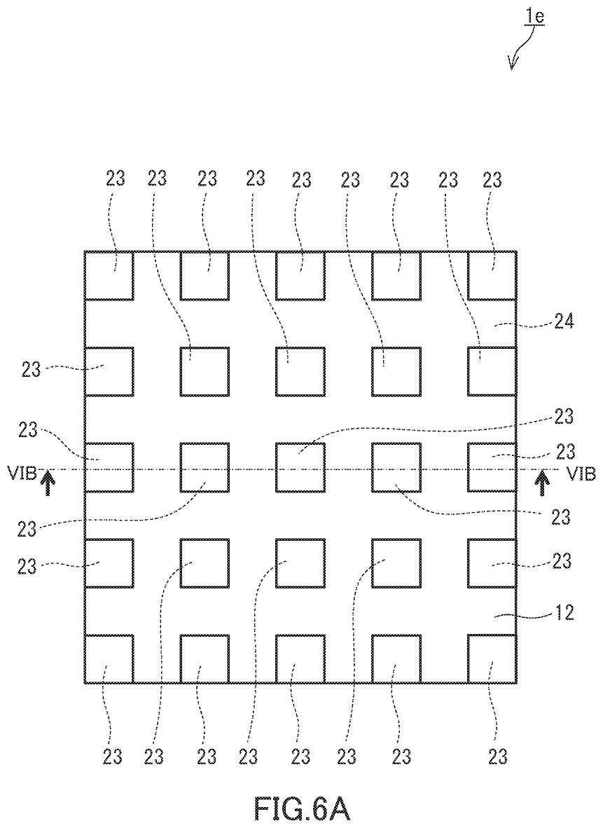

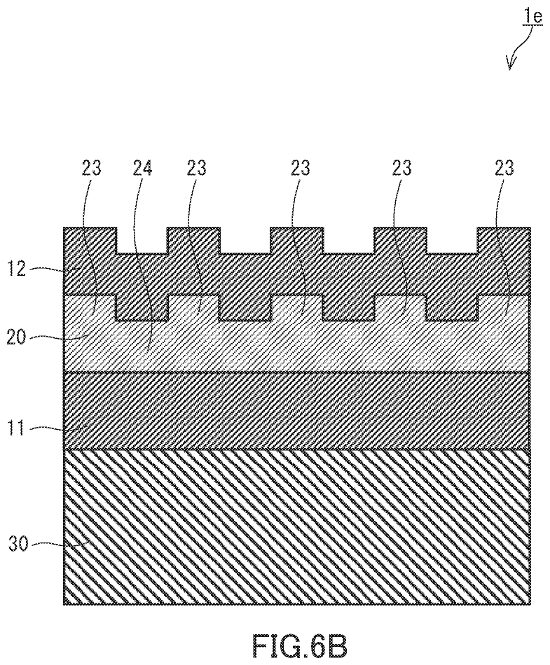

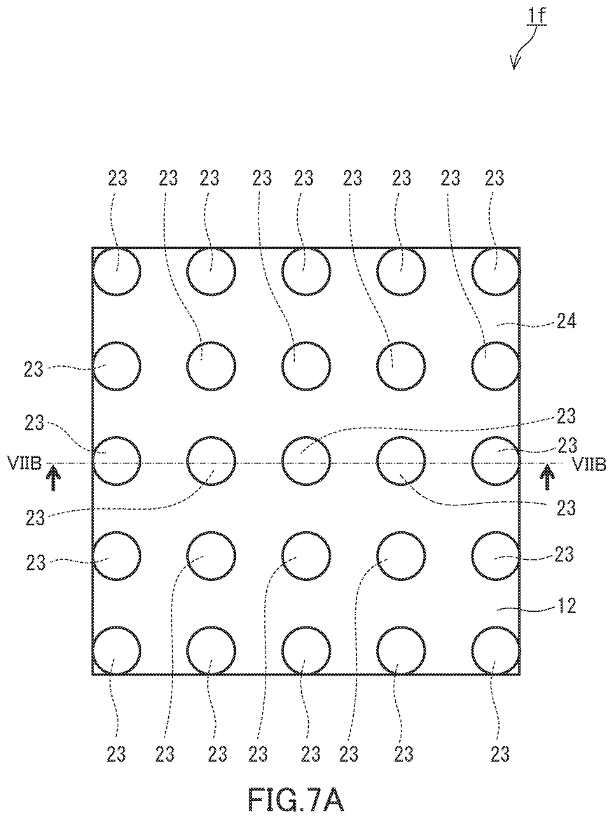

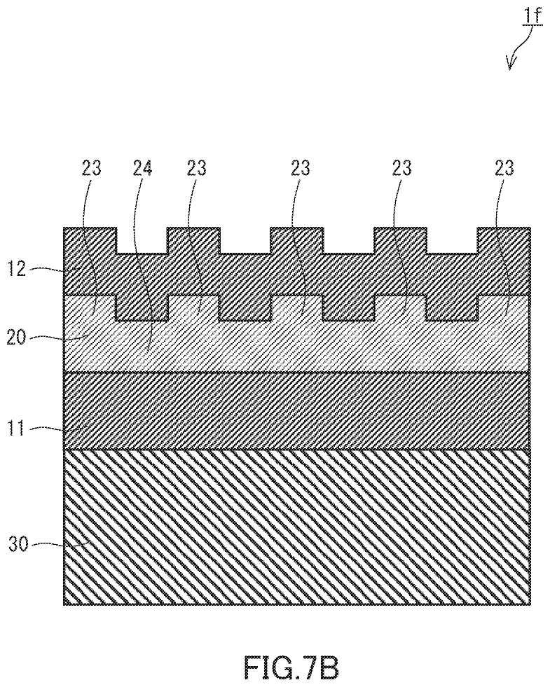

FIGS. 5A and 5B respectively show a plan view and a cross-sectional view of a capacitor 1d according to yet another example of the embodiment of the present disclosure. FIGS. 6A and 6B respectively show a plan view and a cross-sectional view of a capacitor 1e according to yet another example of the embodiment of the present disclosure. FIGS. 7A and 7B respectively show a plan view and a cross-sectional view of a capacitor 1f according to yet another example of the embodiment of the present disclosure. The capacitors 1d, 1e, and 1f are configured in the same manner as the capacitor 1a unless otherwise described. The components of the capacitors 1d, 1e, and 1f that are the same as or correspond to the components of the capacitor 1a are denoted by the same reference characters, and detailed descriptions of such components are omitted. The description given for the capacitor 1a is applicable to the capacitors 1d, 1e, and 1f unless there is a technical inconsistency.

As shown in FIGS. 5A, 5B, 6A, 6B, 7A, and 7B, the antiferroelectric layer 20 includes a plurality of particular regions 23 in each of the capacitors 1d, 1e, and 1f. Each particular region 23 has a particular thickness. In other words, the antiferroelectric layer 20 has a uniform thickness in the particular regions 23. Alternatively, the antiferroelectric layer 20 is considered to have a uniform thickness in the particular regions 23. For example, the antiferroelectric layer 20 is considered to have a uniform thickness in the particular regions 23 when a difference between the largest value and the smallest value of average thicknesses determined for the particular regions 23 is equal to or less than 10% of the smallest value, the average thicknesses each being an average of thicknesses at 10 or more points randomly selected in each particular region 23. The particular regions 23 are disposed apart from each other when the antiferroelectric layer 20 is viewed in plan from the second electrode layer 12. With such a structural feature, for example, a load is likely to be applied to dispersed positions on the antiferroelectric layer 20. Consequently, when a layered structure or a wound structure is formed of the capacitor 1d, the capacitor 1d is likely to have a high robustness. The particular regions 23 project, for example, in the thickness direction of the antiferroelectric layer 20.

As shown in FIGS. 5A, 5B, 6A, 6B, 7A, and 7B, in each of the capacitors 1d, 1e, and 1f, the particular regions 23 are disposed regularly when the antiferroelectric layer 20 is viewed in plan from the second electrode layer 12. With such a structural feature, the capacitor 1d is likely to have a high robustness more reliably. In the cross-sections shown in FIGS. 5B, 6B, and 7B, the thickness of the antiferroelectric layer 20 varies at regular intervals. The capacitors 1d, 1e, and 1f may be modified such that the particular regions 23 are disposed randomly when the antiferroelectric layer 20 is viewed in plan from the second electrode layer 12.

As shown in FIG. 5A, each of the particular regions 23 in the capacitor 1d is in a shape of a belt parallel to another belt when the antiferroelectric layer 20 is viewed in plan from the second electrode layer 12. With such a structural feature, the total area measured when the plurality of particular regions 23 is viewed in plan is likely to be large, and the capacitor 1d is likely to have a high robustness more reliably. The antiferroelectric layer 20 further includes, for example, a plurality of bottom regions 24. As shown in FIG. 5B, the antiferroelectric layer 20 has a smaller thickness in each bottom region 24 than in the particular region 23. Each of the bottom regions 24 is in a shape of a belt parallel to another belt. In the antiferroelectric layer 20, the particular regions 23 and the bottom regions 24 are disposed alternately.

As shown in FIG. 6A, each of the particular regions 23 in the capacitor 1e is in a rectangular shape when the antiferroelectric layer 20 is viewed in plan from the second electrode layer 12. On the other hand, as shown in FIG. 7A, each of the particular regions 23 in the capacitor 1f is in a circular shape when the antiferroelectric layer 20 is viewed in plan from the second electrode layer 12. With such structural features, the capacitors are likely to have a high robustness more reliably. Moreover, the total area measured when the plurality of particular regions 23 is viewed in plan is easily adjustable, and capacity properties of the capacitors are easily adjustable.

In each of the capacitors 1e and 1f, the antiferroelectric layer 20 further includes, for example, the bottom region 24. The antiferroelectric layer 20 has a smaller thickness in the bottom region 24 than in the particular region 23. The bottom region 24 is adjacent to each of the particular region 23 when the antiferroelectric layer 20 is viewed in plan from the second electrode layer 12, and extends continuously in an in-plane direction of the antiferroelectric layer 20.

Each of the particular regions 23 may be in a polygonal shape other than a rectangular shape, may be in an elliptical shape, may be in the shape of a figure made of both a curved line and a straight line, or may be irregular in shape when the antiferroelectric layer 20 is viewed in plan from the second electrode layer 12.

As shown in FIGS. 5B, 6B and 7B, for example, surfaces of the capacitors 1d, 1e, and 1f on the second electrode layer 12 side have projections and recesses. The projections and recesses are attributable to the shape of the antiferroelectric layer 20. The capacitors 1d, 1e, and 1f may be modified such that the surfaces on the second electrode layer 12 side are flat.

### EXAMPLES

Hereinafter, the present disclosure will be described in more detail with reference to examples. The present disclosure is not limited to examples given below.

### Example

A thin TiN film having a thickness of 300 nm was formed on the (100) plane of a Si substrate by RF magnetron sputtering to obtain a first electrode layer. Next, a thin amorphous film was formed on the first electrode layer by RF magnetron sputtering. The composition of the thin amorphous film is Hf_{0.48}Zr_{0.48}Si_{0.04}O₂, which has paraelectricity. In the formation of the thin amorphous film, a metal mask was inserted between a sputtering target and the first electrode layer. The metal mask was moved in two stages in the RF sputtering process, so that the area masked by the metal mask was changed in two stages. The thin amorphous film was formed in this manner to include three regions, namely, a region A, a region B, and a region C, having different thicknesses. The region A has an area of 1 mm² in plan view, and the thin amorphous film has a thickness of 10 nm in the region A. The region B has an area of 1 mm² in plan view, and the thin amorphous film has a thickness of 15 nm in the region B. The region C has an area of 2 mm² in plan view, and the thin amorphous film has a thickness of 20 nm in the region C. RTA was performed in which the Si substrate where the first electrode layer and the thin amorphous film had been formed was heated in a nitrogen atmosphere at 700° C. for 30 seconds. By this RTA, the amorphous structure of the oxide having the composition Hf_{0.48}Zr_{0.48}Si_{0.04}O₂ changed to a crystal structure having antiferroelectricity and a tetragonal structure. An antiferroelectric layer was formed on the first electrode layer in this manner. After that, a thin Au film having a thickness of 100 nm was formed on the antiferroelectric layer by vacuum deposition to obtain a second electrode layer. A capacitor according to Example having three regions with different thicknesses and including an antiferroelectric layer was produced in this manner.

### Comparative Example

A capacitor according to Comparative Example including an antiferroelectric layer having a uniform thickness was produced in the same manner as in Example, except that no metal mask was inserted between the sputtering target and the first electrode layer during the formation of a thin amorphous film. In the capacitor according to Comparative Example, the antiferroelectric layer has an area of 4 mm² in plan view, and the area is equal to the sum of the areas measured in plan view for the regions A, B, and C of the antiferroelectric layer of the capacitor according to Example. In the capacitor according to Comparative Example, the antiferroelectric layer has a thickness of 15 nm.

[Evaluation]

The capacitors according to Example and Comparative Example were subjected to a polarization-electric field measurement using a ferroelectric tester Premier II manufactured by Radiant Technologies Inc. A graph showing a relation between a polarization moment of each capacitor and a magnitude of a voltage applied between the first electrode layer and the second electrode layer was obtained on the basis of the measurement result.

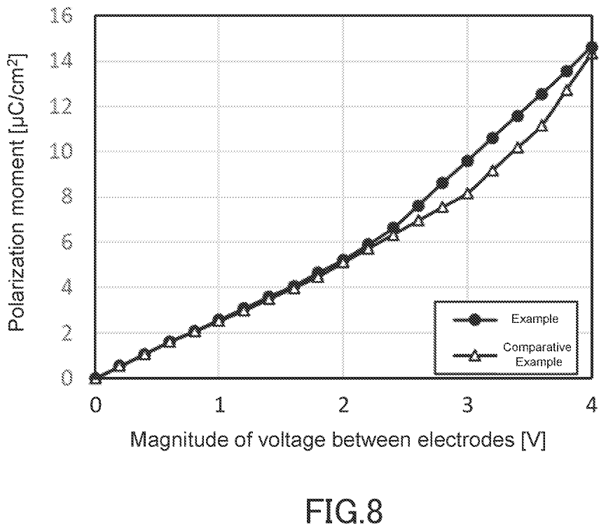

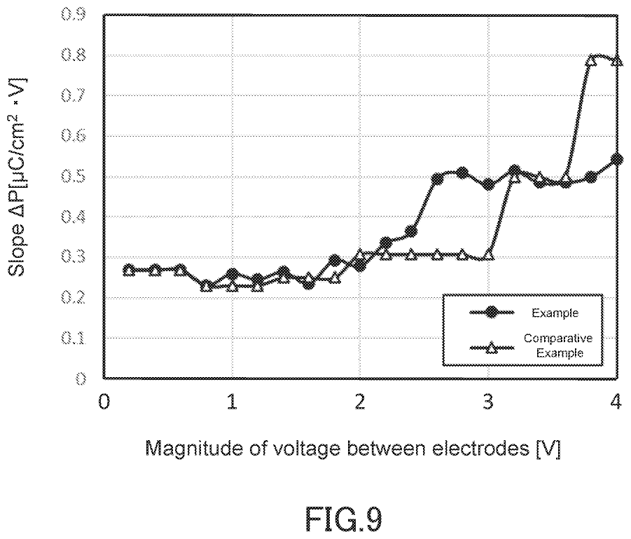

FIG. 8 is the graph showing the relation between the polarization moment of each capacitor and the magnitude of the voltage applied between the first electrode layer and the second electrode layer. FIG. 9 is a graph showing a relation between a slope ΔP of each line in the graph shown in FIG. 8 and the magnitude of the voltage applied between the first electrode layer and the second electrode layer. In FIG. 8, the vertical axis represents the polarization moment of each capacitor, while the horizontal axis represents the magnitude of the voltage applied between the first electrode layer and the second electrode layer. In FIG. 9, the vertical axis represents the slope of each line in the graph shown in FIG. 8, while the horizontal axis represents the magnitude of the voltage applied between the first electrode layer and the second electrode layer.

As shown in FIGS. 8 and 9, when the voltage applied between the first electrode layer and the second electrode layer varies from 0 V to 4 V, the slope ΔP of the line in the graph shown in FIG. 8 does not greatly vary in a particular voltage range in the case of the capacitor according to Example. In other words, for the capacitor according to Example, a ratio of an amount of change of the polarization moment to a certain amount of change of the voltage applied between the first electrode layer and the second electrode layer does not greatly vary in the range of 0 V to 4 V.

Specifically, the slope ΔP of the capacitor according to Example increases from 0.28 to 0.55 in the range of 0 V to 4 V, and is roughly fixed in the range of 2.5 V to 4 V. On the other hand, for the capacitor according to Comparative Example, the polarization moment exponentially increases when the voltage applied between the first electrode layer and the second electrode layer varies from 2.5 V to 4 V. Therefore, as shown in FIG. 9, the slope of the line in the graph shown in FIG. 8 sharply increases in the voltage range of 3 V to 4 V in the case of the capacitor according to Comparative Example. For the capacitor according to Example, the value of ΔP varies within merely approximately in the range of 2 V to 2.5 V, and is roughly fixed in the range of 2.5 V to 4 V. On the other hand, for the capacitor according to Comparative Example, the value of ΔP varies within approximately 0.5 in the range of 3 V to 4 V.

It is understood that for the capacitor according to Example, the ratio of the amount of change of the polarization moment to a certain amount of change of the voltage applied between the electrodes is unlikely to vary in a wide voltage range, compared to the capacitor according to Comparative Example. It is understood that, as for the capacitor including the antiferroelectric layer, because the antiferroelectric layer has a thickness differing from point to point, a relation between the voltage between the electrodes of the capacitor and the amount of electric charge stored in the capacitor can approximate to a direct proportional relationship.

### INDUSTRIAL APPLICABILITY

A variation in dielectric constant is reduced in the entire antiferroelectric layer of the capacitor of the present disclosure, and that makes it easy to design electrical circuits where the capacitor is to be mounted. Therefore, the capacitor of the present disclosure can be included in, for example, electronic devices such as smartphones and tablet terminals, electric automobiles including hybrid cars and plug-in hybrid cars, and energy storage systems combined with power generators such as solar cells or for wind power generation or the like.

What is claimed is:

1. A capacitor comprising:
a first electrode layer;
a second electrode layer; and
an antiferroelectric layer disposed between the first electrode layer and the second electrode layer in a thickness direction of the first electrode layer, wherein
an inner portion of the first electrode layer covers the antiferroelectric layer, the inner portion surrounded by an outermost portion of the first electrode layer when the first electrode layer is viewed in plan,
an inner portion of the second electrode layer covers the antiferroelectric layer, the inner portion surrounded by an outermost portion of the second electrode layer when the second electrode layer is viewed in plan, and
the antiferroelectric layer has a thickness differing from one point to another.

2. The capacitor according to claim 1, wherein the antiferroelectric layer has a thickness of 10 nanometers or more and 1 micrometer or less.

3. The capacitor according to claim 1, wherein a ratio of a maximum of the thickness of the antiferroelectric layer to a minimum of the thickness of the antiferroelectric layer is more than 1 and less than 10.

4. The capacitor according to claim 1, wherein a maximum of the thickness of the antiferroelectric layer is 500 nanometers or less.

5. The capacitor according to claim 1, wherein the thickness of the antiferroelectric layer is smaller than a thickness of the first electrode layer.

6. The capacitor according to claim 1, wherein the thickness of the antiferroelectric layer is smaller than a thickness of the second electrode layer.

7. The capacitor according to claim 1, wherein the thickness of the antiferroelectric layer varies continuously or stepwise in a particular in-plane direction.

8. The capacitor according to claim 7, wherein the thickness of the antiferroelectric layer varies continuously or stepwise from one end to the other end in a particular in-plane direction.

9. The capacitor according to claim 1, wherein
the antiferroelectric layer includes a first region and a second region, the first region having a minimum thickness and having a given area in plan view, the second region having a maximum thickness and having a given area in plan view, and
a ratio of the area of the second region in plan view to the area of the first region in plan view is more than 1 and less than 10.

10. The capacitor according to claim 1, wherein
the antiferroelectric layer includes a connecting portion between a pair of regions having different thicknesses, the connecting portion defining a step corresponding to a difference between the thicknesses of the pair of regions.

11. The capacitor according to claim 1, wherein the antiferroelectric layer includes a connecting portion between a pair of regions having different thicknesses, the connecting portion having a thickness varying continuously or stepwise from one of the pair of regions toward the other.

12. The capacitor according to claim 1, wherein
the antiferroelectric layer includes a plurality of particular regions each having a particular thickness and having a given area in plan view, and
the particular regions are disposed apart from each other when the antiferroelectric layer is viewed in plan from the second electrode layer.

13. The capacitor according to claim 12, wherein the particular regions are disposed regularly when the antiferroelectric layer is viewed in plan from the second electrode layer.

14. The capacitor according to claim 12, wherein each of the particular regions is in a shape of a belt parallel to another belt when the antiferroelectric layer is viewed in plan from the second electrode layer.

15. The capacitor according to claim 12, wherein each of the particular regions is in a circular or rectangular shape when the antiferroelectric layer is viewed in plan from the second electrode layer.

16. The capacitor according to claim 1, wherein the antiferroelectric layer includes a metal oxide including at least one of hafnium and zirconium.

17. The capacitor according to claim 1, further comprising a support, wherein
the first electrode layer is disposed between the support and the antiferroelectric layer in the thickness direction of the first electrode layer.

18. The capacitor according to claim 17, wherein the support has no empty space overlapping the antiferroelectric layer in plan view.

19. An electrical circuit comprising the capacitor according to claim 1.

20. A circuit board comprising the capacitor according to claim 1.

21. An electronic device comprising the capacitor according to claim 1.

22. An electricity storage device comprising the capacitor according to claim 1.
